(19) United States
(12) Patent Application Publication
(10) Pub. No.: US 2014/0326290 A1
(43) Pub. Date: Nov. 6, 2014

(54) SOLAR CELL AND SOLAR CELL MODULE

(71) Applicant: Dong Keun Lee, Seoul (KR)

(72) Inventor: Dong Keun Lee, Seoul (KR)

(73) Assignee: LG INNOTEK CO., LTD., Seoul (KR)

(21) Appl. No.: 14/351,340

(22) PCT Filed: Jun. 21, 2012
(86) PCT No.: PCT/KR2012/004920

§ 371 Date: Jul. 1, 2014

(30) Foreign Application Priority Data
Oct. 11, 2011 (KR) 10-2011-0103823

(51) Int. Cl. H01L 31/05; H01L 31/18; H01L 31/0224

(52) U.S. Cl. CPC H01L 31/0508; H01L 31/022425; H01L 31/022466; H01L 31/1884; H01L 31/0322
USPC 136/244; 136/256

(57) ABSTRACT

A solar cell according to the embodiment includes a back electrode layer formed on a support substrate and including a first groove for exposing the support substrate; a light absorbing layer formed on the back electrode layer and on a part of the first groove; a front electrode layer on the light absorbing layer; and a connection wire disposed at one lateral side of the front electrode, at one lateral side of the light absorbing layer and on the first groove. The embodiment provides a solar cell module using the solar cell and a method of fabricating the same.

### TECHNICAL FIELD

The embodiment relates to a solar cell and a solar cell module.

### BACKGROUND ART

Solar cells may be defined as devices to convert light energy into electric energy by using a photovoltaic effect of generating electrons when light is incident onto a P-N junction diode. The solar cell may be classified into a silicon solar cell, a compound semiconductor solar cell mainly including a group I-III-VI compound or a group III-V compound, a dye-sensitized solar cell, and an organic solar cell according to materials constituting the junction diode.

A solar cell made from CIGS (CuInGaSe), which is one of group I-III-VI Chal-copyrite-based compound semiconductors, represents superior light absorption, higher photoelectric conversion efficiency with a thin thickness, and superior electro-optic stability, so the CIGS solar cell is spotlighted as a substitute for a conventional silicon solar cell.

In general, a CIGS solar cell can be prepared by sequentially forming a back electrode layer, a light absorbing layer, a buffer layer and a front electrode layer on a glass substrate. The substrate can be prepared by using various materials, such as soda lime glass, stainless steel and polyimide (PI). The back electrode layer mainly includes molybdenum (Mo) having low specific resistance and thermal expansion coefficient similar to that of the glass substrate.

The light absorbing layer is a P type semiconductor layer and mainly includes CuInSe₂ or Cu(InxGa₁-x)Se₂, which is obtained by replacing a part of In with Ga. The light absorbing layer can be formed through various processes, such as an evaporation process, a sputtering process, a selenization process or an electroplating process.

The buffer layer is disposed between the light absorbing layer and the front electrode layer, which represent great difference in lattice coefficient and energy bandgap, to form a superior junction therebetween. The buffer layer mainly includes cadmium sulfide (CdS) prepared through chemical bath deposition (CBD).

The front electrode layer is an N type semiconductor layer and forms a PN junction with respect to the light absorbing layer together with the buffer layer. In addition, since the front electrode layer serves as a transparent electrode at a front surface of the solar cell, the front electrode layer mainly includes aluminum-doped zinc oxide (AZO) having the superior light transmittance and electric conductivity.

FIG. 1 is a sectional view showing the structure of a solar cell module according to the related art. Referring to FIG. 1, the solar cell module includes unit cells spaced apart from each other at a regular interval and connected with each other in series. The structure of the solar cell module can be achieved through three pattering processes (P1 to P3). However, if the solar cell module is fabricated through the three pattering processes (P1 to P3), the patterning time may be increased, so that the process time may be increased and the size of a non-active area (NAA) formed through the patterning processes may be enlarged.

### DISCLOSURE OF INVENTION

### Technical Problem

The embodiment provides a solar cell and a solar cell module, which can improve the efficiency and can be readily fabricated.

### Solution to Problem

A solar cell according to the embodiment includes a back electrode layer formed on a support substrate and including a first groove for exposing the support substrate; a light absorbing layer formed on the back electrode layer and on a part of the first groove; a front electrode layer on the light absorbing layer; and a connection wire disposed at one lateral side of the front electrode, at one lateral side of the light absorbing layer and on the first groove.

A solar cell module according to the embodiment includes a first solar cell including a first back electrode, a first light absorbing part and a first front electrode, which are sequentially formed on a support substrate; a second solar cell including a second back electrode, a second light absorbing part and a second front electrode, which are sequentially formed on the support substrate; and a connection wire disposed between the first and second solar cells to electrically connect the first front electrode with the first back electrode.

A method of fabricating a solar cell module according to the embodiment includes the steps of forming a back electrode layer including a first groove on a support substrate; forming a light absorbing layer on the back electrode layer; forming a front electrode layer on the light absorbing layer; forming a second groove through the light absorbing layer and the front electrode layer such that the second groove overlaps with the first groove; and forming a connection wire on the first and second grooves.

### Advantageous Effects of Invention

According to the method of fabricating the solar cell module of the embodiment, the solar cell module can be fabricated through P1 and P2 patterning processes without performing the P3 patterning process, so that the process time can be shortened and the fabrication cost can be reduced. In addition, according to the method of fabricating the solar cell module of the embodiment, the third groove can be simply formed through the inclined sputtering process without performing the additional pattering process. Further, the solar cell module may have the novel serial connection structure due to the third groove.

In addition, the non-active area (NAA), which is formed through the P3 patterning process in the related art, can be removed in the solar cell module according to the embodiment. Thus, the solar cell module according to the embodiment can reduce the non-active area (NAA), so that the photoelectric conversion efficiency can be improved.

### BRIEF DESCRIPTION OF DRAWINGS

FIG. 1 is a sectional view showing a solar cell module according to the related art;

FIG. 2 is a sectional view showing a solar cell according to the embodiment;

FIG. 3 is a sectional view showing a solar cell module according to the embodiment; and

FIGS. 4 to 8 are sectional views showing a method of fabricating a solar cell module according to the embodiment.

### MODE FOR THE INVENTION

In the description of the embodiments, it will be understood that when a substrate, a layer, a film or an electrode is referred to as being “on” or “under” another substrate, another layer, another film or another electrode, it can be “directly” or “indirectly” on the other substrate, the other layer, the other film, or the other electrode, or one or more intervening layers may also be present. Such a position of the layer has been described with reference to the drawings. The size of the elements shown in the drawings may be exaggerated for the purpose of explanation and may not utterly reflect the actual size.

FIG. 2 is a sectional view showing a solar cell according to the embodiment. Referring to FIG. 2, the solar cell according to the embodiment includes a support substrate 100, a back electrode layer 200 including a first groove P1, a light absorbing layer 300, a buffer layer 400, a high-resistance buffer layer 500, a front electrode layer 600, and a connection wire 700.

The support substrate 100 has a plate shape and supports the back electrode layer 200, the light absorbing layer 300, the buffer layer 400, the high-resistance buffer layer 500 and the front electrode layer 600. The support substrate 100 may be transparent, and may be rigid or flexible.

In addition, the support substrate 100 may include an insulator. For example, the support substrate 100 may include a glass substrate, a plastic substrate, or a metallic substrate. In more detail, the support substrate 100 may include a soda lime glass substrate. In addition, the support substrate 100 may include a ceramic substrate including alumina, stainless steel, or polymer having a flexible property.

The back electrode layer 200 is provided on the support substrate 100. The back electrode layer 200 is a conductive layer. The back electrode layer 200 may include one selected from the group consisting of molybdenum (Mo), gold (Au), aluminum (Al), chrome (Cr), tungsten (W), and copper (Cu). Among the above materials, the Mo has a thermal expansion coefficient similar to that of the support substrate 100, so the Mo may improve the adhesive property and prevent the back electrode layer 200 from being delaminated from the substrate 100.

The back electrode layer 200 includes a first groove P1. The back electrode layer 200 can be patterned by the first groove P1. In addition, the first groove P1 can be variously arranged in the form of a stripe as shown in FIG. 2 or a matrix.

The light absorbing layer 300 is provided on the back electrode layer 200. The light absorbing layer 300 includes a group I-III-VI compound. For example, the light absorbing layer 300 may have the CIGSS (Cu(IN,Ga)(Se,S)₂) crystal structure, the CISS (Cu(IN)(Se,S)₂) crystal structure or the CGSS (Cu(Ga)(Se,S)₂) crystal structure.

The buffer layer 400 is provided on the light absorbing layer 300. The buffer layer 400 may include CdS, ZnS, InXSY or InXSeYZn(O, OH). The buffer layer 400 may have the thickness in the range of about 50 nm to about 150 nm and the energy bandgap in the range of about 2.2 eV to about 2.4 eV.

The high-resistance buffer layer 500 is disposed on the buffer layer 400. The high-resistance buffer layer 500 includes i-ZnO, which is not doped with impurities. The high-resistance buffer layer 500 may have the energy bandgap in the range of about 3.1 eV to about 3.3 eV. The high-resistance buffer layer 500 can be omitted.

The front electrode layer 600 may be provided on the light absorbing layer 300. For example, the front electrode layer 600 may directly make contact with the high-resistance buffer layer 500 formed on the light absorbing layer 300.

The front electrode layer 600 may include a transparent conductive material. In addition, the front electrode layer 600 may have the characteristics of an N type semiconductor. In this case, the front electrode layer 600 forms an N type semiconductor with the buffer layer 400 to make a PN junction with the light absorbing layer 300 serving as a P type semiconductor layer. For instance, the front electrode layer 600 may include aluminum-doped zinc oxide (AZO). The front electrode layer 600 may have a thickness in the range of about 100 nm to about 500 nm.

The connection wire 700 is disposed at one lateral side of the solar cell. The connection wire 700 electrically connects the solar cell with another solar cell adjacent to the solar cell.

The connection wire 700 may include a material the same as that of the front electrode layer 600. For instance, the connection wire 700 may be formed by using Al-doped zinc oxide (AZO).

In detail, the connection wire 700 can be disposed at one lateral side of the back electrode layer 200, the light absorbing layer 300, the buffer layer 400, the high-resistance buffer layer 500 and the front electrode layer 600. In addition, the connection wire 700 is disposed on the first groove P1. In detail, the connection wire 700 directly makes contact with the support substrate exposed through the first groove P1.

In addition, the connection wire 700 can be disposed only on a part of the first groove P1. For instance, the connection wire 700 can be disposed on the first groove P1 except for a P1′ region. Thus, the connection wire 700 is spaced apart from the back electrode layer 200 by the P1′ region.

Hereinafter, the connection wire 700 will be described in more detail with reference to FIG. 3. FIG. 3 is a sectional view showing the solar cell module according to the embodiment.

Referring to FIG. 3, the solar cell module according to the embodiment includes first and second solar cells C1 and C2 disposed on the support substrate 100 and the connection wire 700 interposed between the first and second solar cells C1 and C2. The first and second solar cells C1 and C2 refer to adjacent solar cells. In addition, although only two solar cells are shown and described in FIG. 3 and the embodiment, the embodiment is not limited thereto. The solar cell module according to the embodiment may include a plurality of solar cells.

The connection wire 700 is disposed at one lateral side of the first solar cell C1 while being spaced apart from one lateral side of the second solar cell C2. At this time, the one lateral side of the second solar cell C2 refers to the lateral side adjacent to one lateral side of the first solar cell C1. That is, the one lateral side of the second solar cell C2 may face the one lateral side of the first solar cell C1.

In detail, the connection wire 700 is disposed at one lateral side of a first back electrode 210, a first light absorbing part 310, a first buffer part 410, a first high-resistance buffer part 510 and a first front electrode 610 of the first solar cell C1, respectively. At this time, the first back electrode 210 is spaced apart from the connection wire 700 by the P1′ region such that the first back electrode 210 can be electrically separated from the connection wire 700. In addition, the connection wire 700 can directly make contact with one lateral side of the first back electrode 210, the first light absorbing part 310, the first buffer part 410, the first high-resistance buffer part 510 and the first front electrode 610.

In addition, the connection wire 700 can be disposed on the first groove P1. In detail, the connection wire 700 can directly make contact with the support substrate exposed through the first groove P1. The first groove P1 refers to the pattern region for separating the first back electrode 210 from a second back electrode 220.

In addition, the connection wire 700 can directly make contact with one lateral side of the second back electrode 220 and/or the top surface of the second back electrode 220. That is, the connection wire 700 can be formed on a part of the second groove P2 where the second back electrode 220 is formed. Thus, the first front electrode 610 of the first solar cell C1 can be electrically connected to the second back electrode 220 by the connection wire 700.

In addition, the connection wire 700 is spaced apart from one lateral side of the second solar cell C2 by a third groove P3. That is, the first solar cell can be separated from the second solar cell by the third groove P3.

According to one embodiment, a width of the connection wire 700 may be reduced proportionally to the distance with respect to the support substrate 100, but the embodiment is not limited thereto. For instance, the connection wire 700 may include a first connection region 710 formed between the first and second back electrodes 210 and 220 and a second connection region 720 formed between the first and second front electrodes 610 and 620. The first and second connection regions 710 and 720 are shown as if they are distinguished from each other, but this is illustrative purpose only. Actually, the first and second connection regions 710 and 720 may be integrally formed with each other. In addition, the width of the first connection region 710 may be larger than the width of the second connection region 720, but the embodiment is not limited thereto.

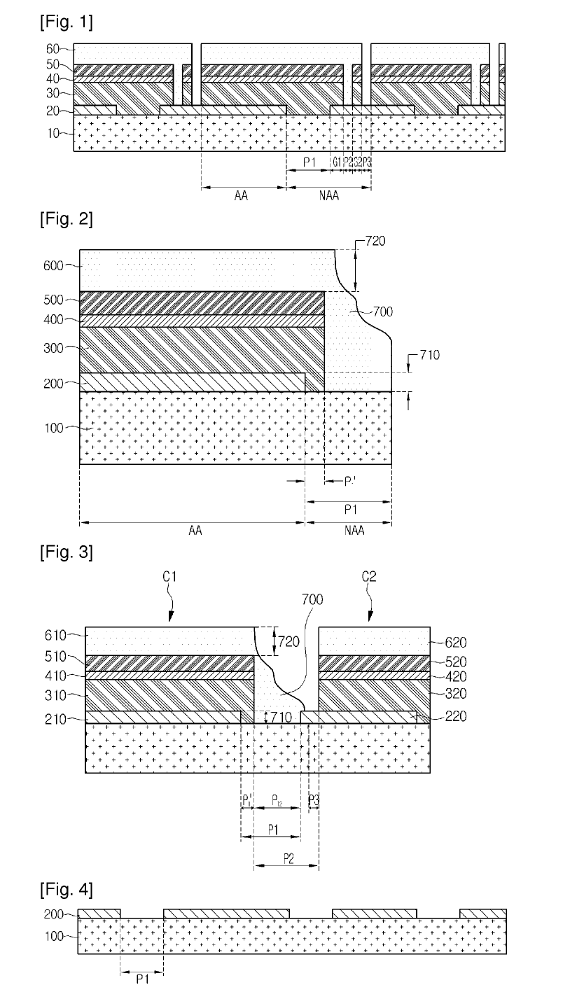

Referring to FIGS. 1 and 3, different from the related art, the solar cell module according to the embodiment may not include G1 and G2 regions. The G1 and G2 regions are non-active areas (NAA) to which electrons generated by solar light may not be transferred. Thus, the solar cell module according to the embodiment can reduce the non-active area (NAA), thereby improving the photoelectric conversion efficiency.

FIGS. 4 to 8 are sectional views showing the method of fabricating the solar cell module according to the embodiment. The above description about the solar cell and the solar cell module will be incorporated herein by reference.

Referring to FIG. 4, the back electrode layer 200 is formed on the support substrate 100. The back electrode layer 200 may be formed through a PVD (Physical Vapor Deposition) scheme or a plating scheme.

The back electrode layer 100 includes the first groove P1. That is, the back electrode layer 200 can be patterned by the first groove P1. The first groove P1 may have various shapes, such as a stripe shape shown in FIG. 3 or a matrix shape.

For instance, the width of the first groove P1 may be in the range of about 50 μm to about 150 μm. In detail, the width of the first groove P1 may be in the range of about 100 μm to about 120 μm, but the embodiment is not limited thereto. According to the embodiment, the first groove P1 is widened as compared with the first groove according to the related art, so an overlap region P12 of the first and second grooves P1 and P2 can be formed in the subsequent process.

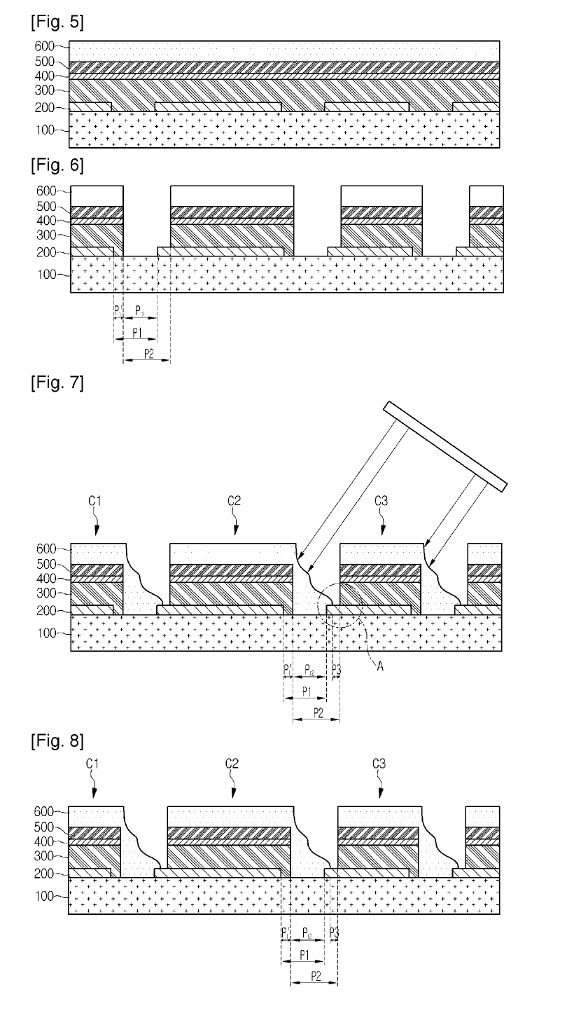

Referring to FIG. 5, the light absorbing layer 300, the buffer layer 400, the high-resistance buffer layer 500 and the front electrode layer 600 are formed on the back electrode layer 200.

The light absorbing layer 300 may be formed through various schemes such as a scheme of forming a Cu(In,Ga)Se₂ (CIGS) based light absorbing layer 300 by simultaneously or separately evaporating Cu, In, Ga, and Se and a scheme of performing a selenization process after a metallic precursor layer has been formed.

Regarding the details of the selenization process after the formation of the metallic precursor layer, the metallic precursor layer is formed on the back electrode layer 200 through a sputtering process employing a Cu target, an In target, or a Ga target. Thereafter, the metallic precursor layer is subject to the selenization process so that the Cu (In, Ga) Se₂ (CIGS) based light absorbing layer 300 is formed.

In addition, the sputtering process employing the Cu target, the In target, and the Ga target and the selenization process may be simultaneously performed.

Further, a CIS or a CIG based light absorbing layer 300 may be formed through the sputtering process employing only Cu and In targets or only Cu and Ga targets and the selenization process.

Thereafter, the buffer layer 400 may be formed by depositing CdS on the light absorbing layer 300 through a CBD (Chemical Bath Deposition) scheme. In addition, ZnO is deposited on the buffering layer 400 through the sputtering process, thereby forming the high-resistance buffer layer 500.

Then, the front electrode layer 600 is formed on the high-resistance buffer layer 500. The front electrode layer 600 can be formed by depositing transparent conductive materials on the high-resistance buffer layer 500. The transparent conductive material may include zinc oxide doped with aluminum or boron. For instance, the front electrode layer 600 can be formed by sputtering the zinc oxide doped with aluminum or boron.

Referring to FIG. 6, the second groove P2 is formed through the light absorbing layer 300, the buffer layer 400, the high-resistance buffer layer 500 and the front electrode layer 600. The second groove P2 may have a width in the range of about 120 μm to about 180 μm, in detail, about 140 μm to about 160 μm, but the embodiment is not limited thereto.

The light absorbing layer 300, the buffer layer 400, the high-resistance buffer layer 500 and the front electrode layer 600 may be separated from each other by the second groove P2. For instance, referring to FIG. 3, the first light absorbing part 310 is spaced apart from the second light absorbing part 320 and the first front electrode 610 is spaced apart from the second front electrode 620 by the second groove P2.

The second groove P2 overlaps with the first groove P1, so that the overlap region P12 is formed. The overlap region P12 may have a width in the range of about 20 μm to about 80 μm, in detail, about 40 μm to about 60 μm, but the embodiment is not limited thereto. According to the embodiment, the second groove P2 overlaps with the first groove P1, so that the non-active area (NAA) formed by the grooves can be reduced. Thus, the solar cell module fabricated according to the method of the embodiment may have the improved photoelectric conversion efficiency.

Referring to FIGS. 7 and 8, the connection wire 700 is formed on the first and second grooves P1 and P2. The connection wire 700 may be formed on a part of the first and second grooves P1 and P2. For instance, the connection wire 700 may be selectively formed on the first and second grooves P1 and P2 except for the P1′ region and P3 region. In addition, the connection wire 700 may be formed at one lateral side of the back electrode layer 200, the light absorbing layer 300 and the front electrode layer 600, respectively.

The connection wire 700 can be formed through the process used to form the front electrode layer 600. For instance, the connection wire 700 can be formed through the sputtering process. That is, the front electrode layer 600 and the connection wire 700 can be formed by performing the sputtering process while varying the inclination angle of the sputtering device.

According to the embodiment, the third groove P3 can be formed when the connection wire 700 is formed without performing the additional patterning process. For instance, in the case that the connection wire 700 is formed at one lateral side of the second solar cell C2, sputtering particles may not reach an A region, which is blocked by the third solar cell C3. Thus, the third groove P3 can be automatically formed due to the shadow effect of the third solar cell C3. The solar cells C1, C2, C3 . . . and Cn can be separated from each other by the third groove P3.

As described above, according to the method of fabricating the solar cell module of the embodiment, the patterning process to form the third groove P3 can be omitted, so that the process time can be shortened and the fabrication cost can be reduced.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effects such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A solar cell comprising:
a back electrode layer formed on a support substrate and including a first groove for exposing the support substrate;
a light absorbing layer formed on the back electrode layer and on a part of the first groove;
a front electrode layer on the light absorbing layer; and
a connection wire disposed at one lateral side of the front electrode, at one lateral side of the light absorbing layer and on the first groove.

2. The solar cell of claim 1, wherein the light absorbing layer is disposed on a top surface of the back electrode layer and at one lateral side of the back electrode layer.

3. The solar cell of claim 2, wherein the connection wire comprises:
a first connection region spaced apart from one lateral side of the back electrode layer; and
a second connection region directly making contact with one lateral side of the front electrode layer,
wherein a width of the first connection region is wider than a width of the second connection region.

4. The solar cell of claim 3, wherein the first connection region is integrally formed with the second connection region.

5. A solar cell module comprising:
first solar cell including a first back electrode, a first light absorbing part and a first front electrode, which are sequentially foamed on a support substrate;
a second solar cell including a second back electrode, a second light absorbing part and a second front electrode, which are sequentially formed on the support substrate; and
a connection wire disposed between the first and second solar cells to electrically connect the first front electrode with the first back electrode.

6. The solar cell module of claim 5, wherein the first and second solar cells are arranged in adjacent to each other.

7. The solar cell module of claim 5, wherein the connection wire is disposed at one lateral side of the first solar cell and spaced apart from one lateral side of the second solar cell.

8. The solar cell module of claim 7, wherein the one lateral side of the first solar cell faces the one lateral side of the second solar cell.

9. The solar cell module of claim 5, wherein the connection wire comprises:
a first connection region between the first and second back electrodes; and
a second connection region between the first and second front electrodes,
wherein a width of the first connection region is wider than a width of the second connection region.

10. The solar cell module of claim 9, wherein the first connection region is integrally formed with the second connection region.

11. The solar cell module of claim 5, wherein the first back electrode is spaced apart from a second back electrode by a first groove.

12. The solar cell module of claim 11, wherein the first light absorbing part is spaced apart from the second light absorbing part by a second groove and the first front electrode is spaced apart from the second front electrode by the second groove.

13. The solar cell module of claim 12, wherein the first groove overlaps with the second groove.

14-19. (canceled)

20. The solar cell module of claim 7, wherein the connection wire is disposed at one lateral side of a first back electrode, a first light absorbing part, a first buffer part, a first high-resistance buffer part and a first front electrode of the first solar cell, respectively

21. The solar cell module of claim 7, wherein the connection wire directly make contact with one lateral side of the second back electrode or the top surface of the second back electrode.

22. The solar cell module of claim 7, wherein the connection wire directly make contact with one lateral side of the second back electrode and the top surface of the second back electrode.
